(19) United States
(12) Patent Application Publication
(10) Pub. No.: US 2011/0079250 A1
(43) Pub. Date: Apr. 7, 2011

(54) POST-TEXTURING CLEANING METHOD FOR PHOTOVOLTAIC SILICON SUBSTRATES

(75) Inventors: Karen A. Reinhardt, San Jose, CA (US); Pythias V. Herrera, Hayward, CA (US); Thomas M. Vukosav, Fremont, CA (US)

(73) Assignee: MT SYSTEMS, INC., Fremont, CA (US)

(21) Appl. No.: 12/572,244

(22) Filed: Oct. 1, 2009

(51) Int. Cl. B08B 3/00

(52) U.S. Cl. 134/28

(57) ABSTRACT

An improved method for post-texturing cleaning, surface conditioning, and rinsing silicon wafers or similar surfaces, with particular, although not exclusive, applicability in photovoltaic applications which includes cleaning the surfaces sequentially with dilute HF/HCl and dilute oxidizing rinse, particularly following texturing with concentrated HF/HNO3 and/or KOH. The method allows for the recycling of the oxidizing rinse in the dilute HF/HCl and other upstream rinse steps.

### BACKGROUND OF THE INVENTION

The invention relates to a new methods for post-texturing cleaning, surface conditioning, and rinsing silicon wafers or similar surfaces, with particular, although not exclusive, applicability in photovoltaic applications.

Texturing of the wafer surface is usually the first step of the single emitter photovoltaic (PV) manufacturing process for both mono- and multi-crystalline silicon wafers. The texturing process roughens the surface and reduces the reflection of the silicon surface by etching along crystal planes and grain boundaries to increase the surface area to provide more light trapping. In addition to texturing, the initial wet chemical process bath or baths also must remove saw-damage, undesirable contamination, and condition the silicon surface to be hydrophilic so as to allow uniform doping for the emitter formation.

Two of the most widely used processes, developed at the Energy Research Centre of the Netherlands (“ECN”) and the University of Konstanz (“UKN”) each begin with a concentrated HF/HNO₃ texturing bath that also removes any saw damage. KOH with IPA or a surfactant or NaOH can also be used for texturing, either alone or after the HF/HNO₃. The ECN and UKN processes are disclosed in A. W. Weeber, A. R. Burgers, M. J. A. A. Goris, M. Koppes, E. J. Kossen, N. C. Rieffe, W. J. Soppe, C. J. J. Tool, and J. H. Bultman, 19th European Photovoltaic Solar Energy Conference (2004), and Hauser, et al., U.S. Pat. No. 7,192,885, respectively.

The texturing process composition, used for multi-crystalline wafers, is comprised of 20% to 55% H₂O, 10% to 40% concentrated HF (49 wt %) and 20% to 60% concentrated HNO₃ (approximately 65 wt %), with additives such as acetic acid (H-AC) and a surfactant. The texturing process is carried out at ambient or lower temperature with a controllable etch rate. Other texturing composition ranges can also be used. Typically, the wafers are exposed to the chemical between 1 and 5 minutes.

For mono-crystalline silicon, the preferred texturing solution is alkaline-based. Dilute NaOH solutions or KOH solutions, with and without additives such as isopropyl alcohol (IPA) or ethylene glycol, are suitable for texturing, particularly for mono-crystalline silicon. Although acid texturing baths, including those described above for multi-crystalline wafers can be used, a KOH or NaOH bath is used subsequently to remove the porous silicon that remains on the surface. An HF/HCl bath is typically performed after the alkaline hydroxide step to facilitate removal of the mobile ions, metallic contamination, and to strip the chemical oxide. The final oxidation step creates a homogeneous hydrophilic surface allowing uniform phosphorus doping to create the emitter.

The use of dilute chemical baths in processing silicon wafers is known in the art as exemplified by Olesen, et al., U.S. Pat. No. 6,158,445, the techniques outlined by researchers at IMEC published in Proceedings of the 7th International Symposium on Cleaning, SCP Global Technologies, Boise, Id., May 1-3, 2000; Kashdoush, et al., U.S. Pat. No. 6,837,944; Tsao, et al., U.S. Pat. No. 6,165,279; and Puri, et al., U.S. Pat. No. 6,681,781. Moreover, it is well-known in the art to use a dilute HCl rinse after SC-1 baths in semiconductor manufacturing.

However, most such methods contemplate a separate water rinse or other neutralizing method performed after the dilute chemical bath. De-ionized water (DIW) rinsing or an equivalent is generally required because these methods are intended for use in semiconductor manufacturing where contamination levels on the wafer surface must be lower than those for solar cell manufacturing. There is no suggestion of how rinse water or the dilute chemical baths could be recycled and/or reused.

The objective of the current invention to provide a method for post-texturing and cleaning baths for silicon wafers and the like that reduces the amount of chemicals and water used in the process while retaining an acceptable level of cleansing and surface conditioning.

### BRIEF SUMMARY OF THE INVENTION

The present invention discloses an improved rising process for the post-texturing and cleaning baths for silicon wafers and similar surfaces that is especially well-suited to silicon wafers intended to be used for photovoltaic applications. The inventors recognized that for photovoltaic and similar applications a dilute bath used for one step in the process can be reused in other steps because the purity and surface conditioning requirements are not as stringent as with semiconductor wafers. Thus, after the texturing step, rather than using concentrated chemical baths for cleaning and water rinses with new rinse water after these post-texturing baths, the present invention replaces the concentrated chemical baths and subsequent water rinses with combined rinsing and cleaning steps using dilute chemical baths. This replacement also allows for the reuse of chemicals and water recycled from other steps, with or without the addition, or “spiking”, of relatively small amounts of additional chemicals. Furthermore, by using appropriately selected chemicals in a particular order, the current invention allows the number of chemical baths to be reduced. The invention can generally be applied to wet cleaning processes that involve a plurality of chemicals, in individual tanks, with a rinsing step after each chemical step.

In one embodiment, post-texturing chemical baths of the current invention are composed of dilute HF/HCl, followed by dilute SC-1 or O₃/DIW (deionized water) or dilute H₂O₂ or similar dilute formulations. Thus, the concentrated HF/HCl bath and DIW rinse of conventional cleaning processes may be replaced with a dilute HF/HCl rinse, and the final alkaline bath and DIW rinse may be replaced with a dilute SC-1, H₂O₂, or O₃ deionized water (O₃/DIW) rinse or other combination including HF/O₃/DIW.

The use of these dilute rinses allow for the rinsing water to be reused in a controlled manner by cycling the water “upstream” from each rinsing bath. The apparatus for the baths are designed to use the rinsing chemical baths starting with the oxidizing bath (O₃, SC-1 or H₂O₂) going upstream and reusing the water by spiking with HF and/or HCl, and then upstream for rinsing after the KOH, NaOH bath, and finally using this rinsing water with chemicals after the HF/HNO₃ bath, or any combination of KOH and NaOH baths. For certain steps, temperature or time in the bath can be increased to counteract the decrease in reactivity when using the dilute chemicals.

A pre-cleaning and/or post-cleaning process can also be included to remove contamination, as well as metallic, mobile ions and particles, from the surface and to create an oxidized or a oxide-passivated} state. The pre-cleaning step can include a dilute SC-1 rinse followed by a dilute HCl rinse, with or without HF added. The post cleaning step may follow the alkaline or O₃/DIW step with a dilute HF bath with or without HCl added, and then another dilute SC-1 or other alkaline or O₃/DIW bath.

### BRIEF DESCRIPTION OF THE DRAWINGS

FIG. 1 shows a schematic representation of an apparatus to implement a prior art cleaning process after the use of a HF/HCl texturing bath and KOH bath for porous silicon removal.

FIG. 2 shows a schematic representation of an apparatus to implement a prior art cleaning process after the use of a KOH texturing bath.

FIG. 3 is a schematic representation of an embodiment of the invention employing a HF/HNO₃ texturing bath followed by a KOH bath for porous silicon removal.

FIG. 4 is a schematic representation of an embodiment of the invention employing a HF/HNO₃ texturing bath.

FIG. 5 shows the embodiment of FIG. 3 with the addition of paths for reuse of select rinses.

FIG. 6 shows the embodiment of FIG. 3 with the serial use of multiple baths of similar chemical composition and paths for reuse of select rinses.

FIG. 7 is a schematic representation of an embodiment of the invention employing a KOH texturing bath and a path for reuse of the final rinse.

FIG. 8 shows the embodiment of FIG. 7 with the serial use of multiple baths of similar chemical composition and paths for reuse of select rinses.

FIG. 9 shows the embodiment of FIG. 3 with the inclusion of a pre-cleaning step and a first alternative set of paths for the reuse of select rinses.

FIG. 10 shows the embodiment of FIG. 3 with the inclusion of a pre-cleaning step and a second alternative set of paths for the reuse of select rinses.

### DETAILED DESCRIPTION OF THE INVENTION

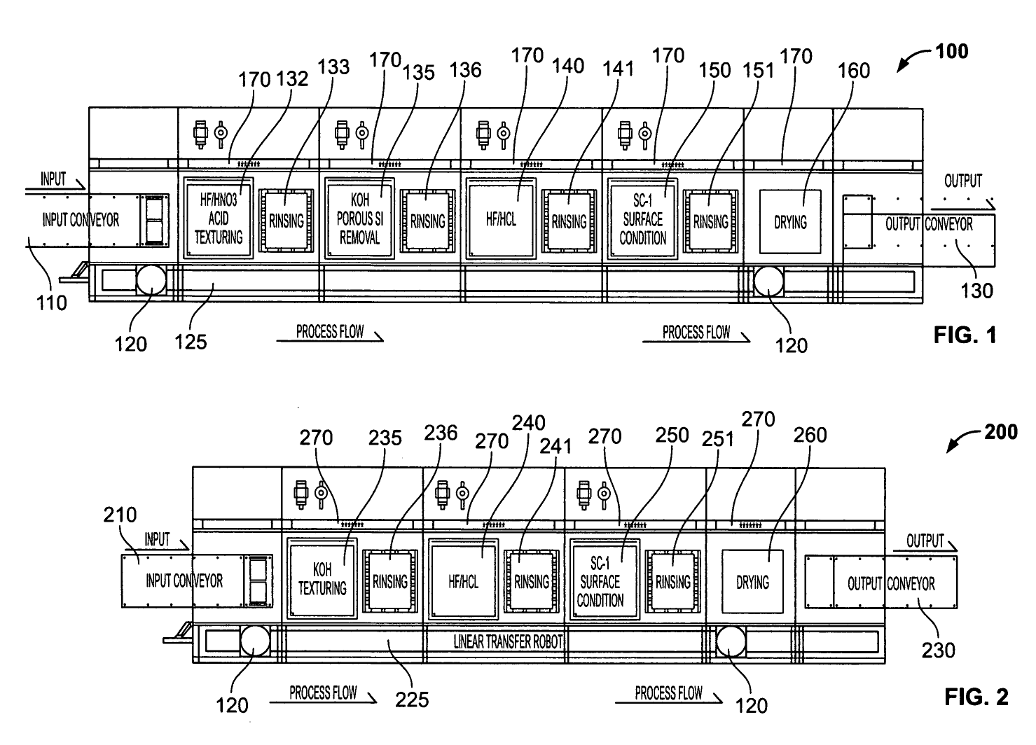

FIGS. 1 and 2 are a schematic representations of a typical apparatus 100, 200 that might be used to implement the texturing and cleaning methods shown in the prior art, and with the modifications described below, for the current invention.

The apparatus include an input conveyer 110, 210, or similar which bring the silicon 120, 220 or other materials to a linear transfer robot 125, 225 for conveying the silicon 120, 220 to the various baths and rinses. An output conveyer 130, 230 can be used to remove the silicon 120, 220 from the apparatus 100, 200 when the processing is complete. It will be understood by those of ordinary skill in the art that all the apparatus discussed would include exhaust means 170 at appropriate locations as well as means (not shown) conventionally used to introduce and remove the chemical baths and DIW rinses all of which could use cooled, ambient, or heated water, depending on the needs of the process.

Further, it will be understood that rinsing can be accomplished by any of a variety of well-known methods, including cascade overflow, quick dump rinsing, and spray rinsing or any combination of these methods. Multiple cycles of these rinsing methods may be used, including full or partial dump rinsing cycles, all of which are well-known in the art. Processing can be dual sided; front and back surface or single sided; front or back surface only. The equipment used for this process can be in-line rollers, immersion, or any applicable equipment that allows dilute processing or can be modified for dilute processing or similar means.

Additions to the process are possible. For example, the rinse water may be subject to gasification or degasification; the rinse may include megasonic cleaning, possibly with the addition of CO₂ to acidify the water and/or N₂ or O₂; additives that gives water unique properties at low concentrations or chelators may be used. Further, filtering of the rinsing water can be performed to remove particles and other undesirable contamination

In FIG. 1, which implements a process suitable for both mono- and multi-crystalline silicon, the first bath is a concentrated HF/HNO₃ texturing bath 132 which can be comprised of 20% to 55% H₂O, 10% to 40% concentrated HF (49 wt %) and 20% to 60% concentrated HNO₃ (approximately 65 wt %), with additives such as acetic acid (H-AC) and a surfactant. The first bath is followed by a DIW rinse 133 using non-recycled water. The second bath is concentrated KOH with IPA, a surfactant 135 to remove any porous silicon. It will be understood that NaOH could replace KOH. The second bath is also followed by a DIW rinse 136 using non-recycled water. The third bath is HF/HCl 140 which removes mobile ions, metallic contamination and the remaining chemical oxide. It, too, is followed by a DIW rinse 141. The final bath is surface conditioning bath of SC-1 150, widely used for removing contaminants, such as particles, in silicon substrate processing, is mixture of ammonium hydroxide (NH₄₀H), hydrogen peroxide (H₂O₂) and de-ionized water in a volume ratio of 1:4:20. The SC-1 bath is also followed by a DIW rinse 151. The silicon 120 or other material then proceeds to a drying step 160 before leaving the apparatus 100.

In FIG. 2, which implements a process suitable for mono-crystalline silicon, the first bath is concentrated KOH with IPA, a surfactant 235 to remove any porous silicon. It will be noted that or with NaOH could replace KOH. The bath is followed by a DIW rinse 236 using non-recycled water. The second bath is HF/HCl 240 and is followed by a DIW rinse 241. The final bath is surface conditioning bath of SC-1 250 and is also followed by a DIW rinse 251. As in the embodiment shown in FIG. 1, the silicon 120 or other material proceeds to a drying step 260 before leaving the apparatus 200.

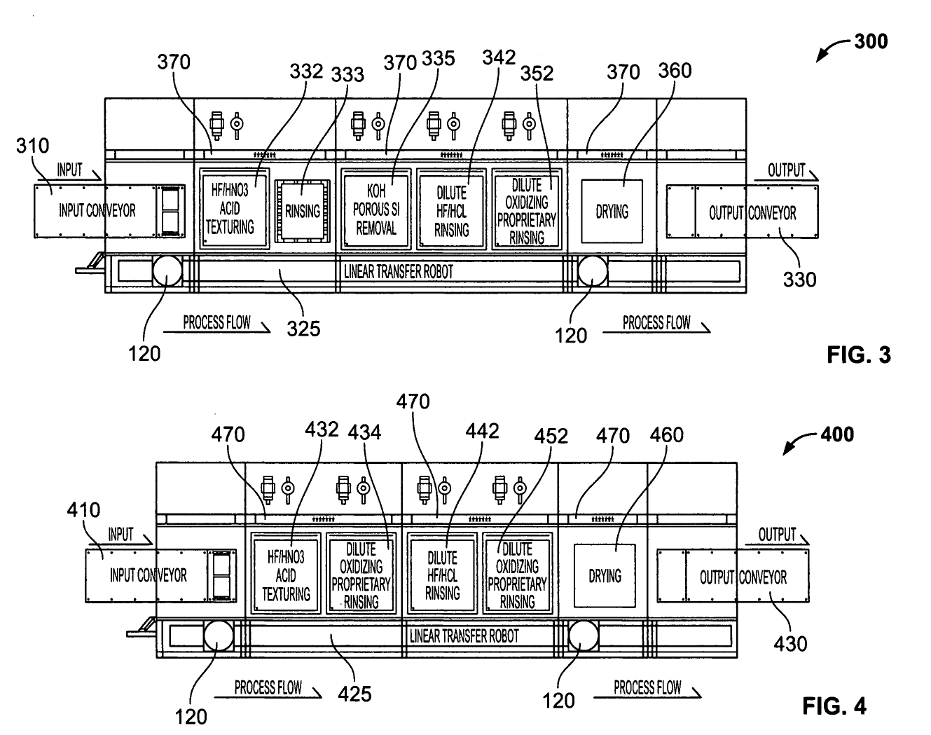

FIG. 3 shows an apparatus 300 suitable for implementing an embodiment of the current invention. This embodiment is suitable for both mono- and multi-crystalline silicon. The apparatus is similar to those in FIGS. 1 and 2, in that it includes an input 310 and output 330 conveyer, a linear transfer robot 325 and exhaust systems 370 at appropriate locations. As in the prior art embodiments, the apparatus of FIG. 3 also includes a first concentrated HF/HNO₃ texturing bath 332 immediately followed by a DIW rinse 333. A second bath of concentrated KOH 335 for porous silicon removal, or, alternatively, a bath of NaOH, follows the DIW rinse. However, the current invention replaces the following DIW rinse and subsequent steps of concentrated HF/HCl bath, DIW rinse, SC-1 bath and DIW rinse with a dilute HF/HCl rinse 342 composed of HF at a concentration of 0.1 to 4.0%, extendible to 0.001 to 15% and HCl at a concentration of 0.01 to 1%, extendible to 0.001 to 15% and a final bath of O₃/DIW 352 at a concentration of 6-20 ppm, extendible to 1-70 ppm. As a preferred alternative, the final bath could also be dilute SC-1 at 100:1:1 or similar, or dilute H₂O₂ at 10:1 or similar, although other concentrations, particularly higher concentrations, could also be used. In combination, these dilute baths simultaneously perform the necessary surface conditioning and rinsing of the silicon. A conventional drying step 360 follows the final bath. It will be understood by those of ordinary skill in the art that appropriate concentrations and ratios of chemicals, as well as the time and temperature of the baths must be selected to achieve the desired surface conditioning result for the particular application in which the silicon 120 or other materials are to be employed. It will be further understood that appropriate conventional means will be used to monitor and adjust the chemical concentrations.

FIG. 4 shows an alternative embodiment for implementing the current invention. As with conventional systems, the apparatus 400 includes an input 410 and output 430 conveyer, a linear transfer robot 425 and exhaust systems 470 at appropriate locations. The embodiment also includes a concentrated HF/HNO₃ texturing bath 332. Further, and significantly, as with the embodiment in FIG. 3, this embodiment includes the use of the dilute HF/HCl rinse 442 and the final bath of O₃/DIW 452 as described in connection with FIG. 3, to perform the necessary surface conditioning and rinsing of the silicon before the drying step 460. However, this embodiment replaces the DIW rinse 333 following the texturing bath 332 and the KOH bath 335, with a single dilute rinse step 434 of HF/O₃ or other oxidizing/Si etching dilute bath. A preferred concentration is HF at a concentration of 0.1 to 4.0%, extendible to 0.001 to 10%, O₃/DIW 352 at a concentration of 6-20 ppm, extendable to 1-70 ppm.

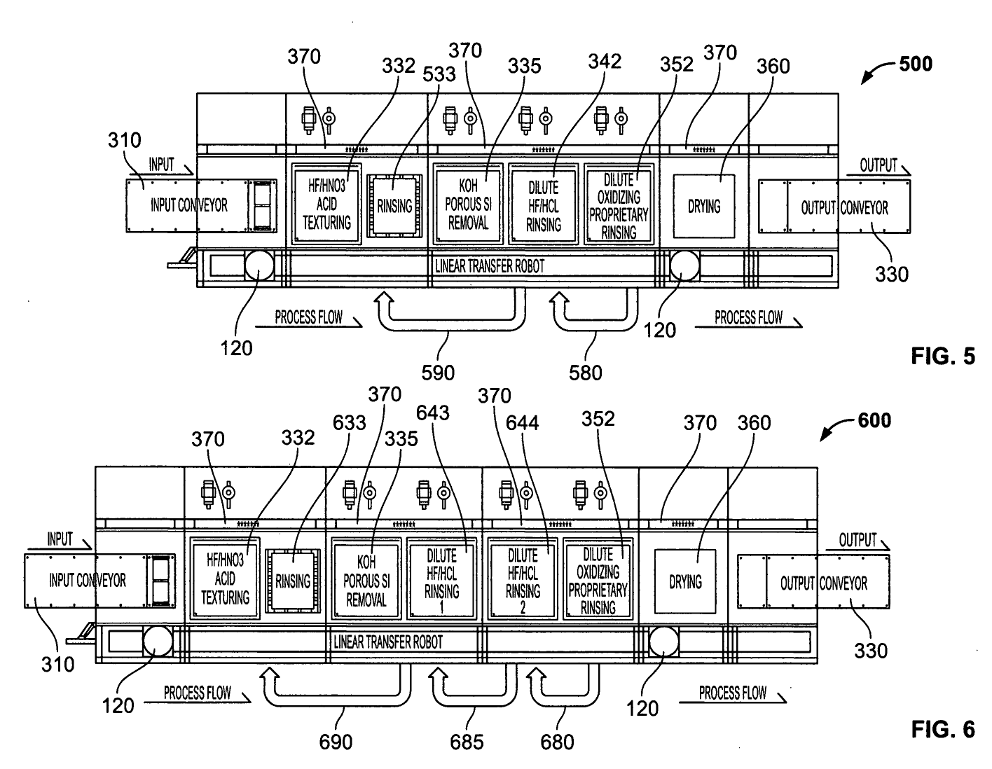

FIG. 5 shows an apparatus 500 that is essentially identical to the embodiment of FIG. 3 but with reuse of the water and chemicals from the final dilute bath 352 in other steps. Incoming high-purity water first is used at the final rinsing cycle 352; either as O₃/DIW or dilute SC-1 at 100:1:1 or similar, or dilute H₂O₂ at 10:1 or similar are potential rinsing baths, this is performed in a recirculated, filtered, ambient bath. The used rinse water is removed from the rinse cycle 352, spiked with HF/HCl and moved 580 to be used as the dilute HF/HCl rinse 342 in a recirculated, filtered, ambient bath after the KOH or NaOH cleaning bath 335. The dilute HF/HCl bath contents are then transferred 590 to a third recirculated, filtered, ambient bath that serves as the rinse 533 after the HF/HNO₃ texturing bath 332, before finally being discarded. It may be spiked with additional oxidizing fluid; hydrogen chloride; hydrogen fluoride; or combined HF/HCl.

It will be understood that while there are a variety of chemicals and concentrations that can be used to obtain the desired surface condition effects, to properly implement this invention the chemical baths that can be reused or recycled must be chosen to meet the combined goal. For example, at the time of transfer of the O₃/DIW bath to the HF/HCl bath, there are residual amounts of O₃ in the bath, but because the concentration of the HF/HCl is more than the O₃ and because O₃ decomposes to molecular oxygen (O₂) with no byproduct of the reaction, it is a preferable bath for both functionality, in that it provides a hydrophilic surface, and reactivity, in that it does not interfere with the functionality of the HF/HCl bath.

As shown in FIG. 6, it is also possible to have multiple dilute baths using the same chemicals. As an example, the process in this apparatus 600 is essentially identical to that shown in FIG. 5, but includes the use of multiple baths. Incoming high-purity water first is used at the final rinsing cycle 352 as described in FIG. 5 in a recirculated filtered, ambient bath. The used rinse water is removed from the rinsing cycle 352, spiked with HF/HCl and moved 680 to another recirculated, filtered, ambient bath 644. After use in bath 644 the rinse water is removed, spiked with more HCl and/or HF, and moved 685 to a recirculated filtered, ambient bath 643 that is directly after the concentrated KOH or NaOH bath 335. Again the rinse is removed and moved 690 to its final use in a recirculated, filtered, ambient bath 633 after the HF/HNO₃ texturing bath. It may be spiked with additional oxidizing fluid; hydrogen chloride; hydrogen fluoride; or combined HF/HCl. After this use the contaminated rinsing water is discarded. It will be understood that the example given is the HF/HCl bath; however, any dilute chemical bath has the potential to be reused in multiple baths of essentially the same chemical composition.

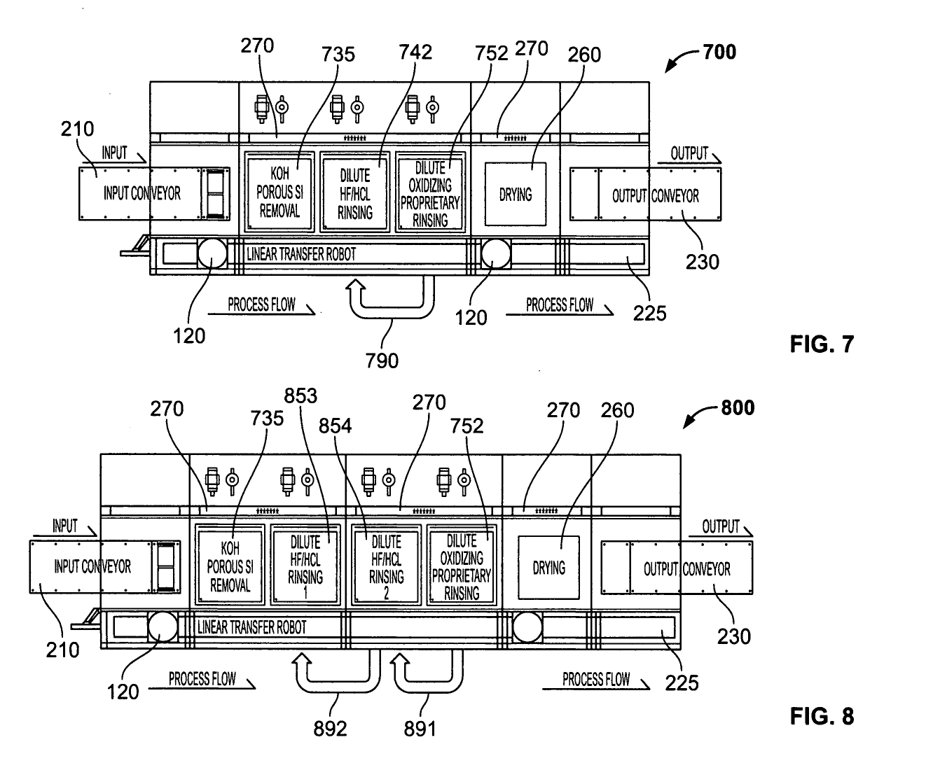

FIG. 7 shows an embodiment of the invention where the initial bath is concentrated KOH 735, similar to the process shown in FIG. 2. As in FIG. 2, the apparatus 700 includes an input 210 and output 230 conveyer, a linear transfer robot 225, appropriately placed exhaust means, 270, and a final drying stage 260. Similar to the embodiment shown in FIG. 3, but without the texturing bath 332 and rinse 333 that precedes the KOH bath 335 used for porous silicon removal, there is no DIW rinse after the KOH bath 735. Instead, as with the previously described embodiments of the invention, the silicon is immediately place into a dilute, recirculated, ambient HF/HCl bath 742 at concentrations previously described in connection with FIG. 3, and then into a final bath 752 of O₃/DIW, dilute SC-1, or dilute H₂O₂ as previously described. This embodiment also employs reuse of the final rinse liquid. After use in the recirculated, filtered, ambient final bath 752, the water is removed, spiked with HF/HCl and moved 790 to be used as the dilute HF/HCl bath 742 before finally being discarded. The process of FIG. 8 is essentially identical, but uses multiple dilute HF/HCl baths 853, 854 rather than the single bath 752. The rinse liquid from the final bath 752 is removed after use, spiked with HF and/or HCl, and moved 891 into the second dilute HF/HCl bath 854. After use in the second dilute HF/HCl bath 854, the liquid is again removed, preferably spiked with more HF and/or HCl, and moved 892 to be used as the first dilute HF/HCl bath 853 immediately after the concentrated KOH bath 735. After use in the first HF/HCl bath 853, the liquid is discarded.

The invention can also be implemented with a pre-cleaning step before the texturing bath. Precleaning is often desirable since the sawing of the wafers slices exposes the pristine silicon to the saw material and also to lubrication, although in certain circumstances and processes, incoming wafers may have sufficiently low contamination levels so that a pre-clean is not needed. Without precleaning, copper and organic lubricating oils build-up in the texturing bath over time and can be distributed throughout the system, even with optimized rinsing. By cleaning the wafer before the texturing process with a dilute bath or series of dilute baths, the life of the entire process and each individual bath can be increased.

The pre-cleaning process is typically composed of a SC-1 bath, either concentrated or dilute, followed by a SC-2 or dilute HCl bath or rinse. But, since a pre-clean with concentrated chemicals may affect the final texturing by exposing grain boundaries or etching the silicon that is detrimental to the final roughness desired, dilute chemical rinses are preferable because they do not affect the texture of the surface. Each of the concentrated SC-1 bath and SC-2 bath is followed by a DIW rinse. However, the dilute HCl rinsed wafers can proceed without additional rinsing into the texturing bath. Hydrofluoric acid may also be spiked into the water or used alone in place of HCl. The “pre-cleaning” baths may also be included after the texturing bath and subsequent rinses; however, the texturing bath would then still be subject to increased contamination. Also, additional precleaning and surface conditioning steps can be added if needed; for example, the sequence SC-1 bath to HF/HCl bath to SC-1 bath to render the surface hydrophilic to allow easier wetting of the surface prior to the texturing bath.

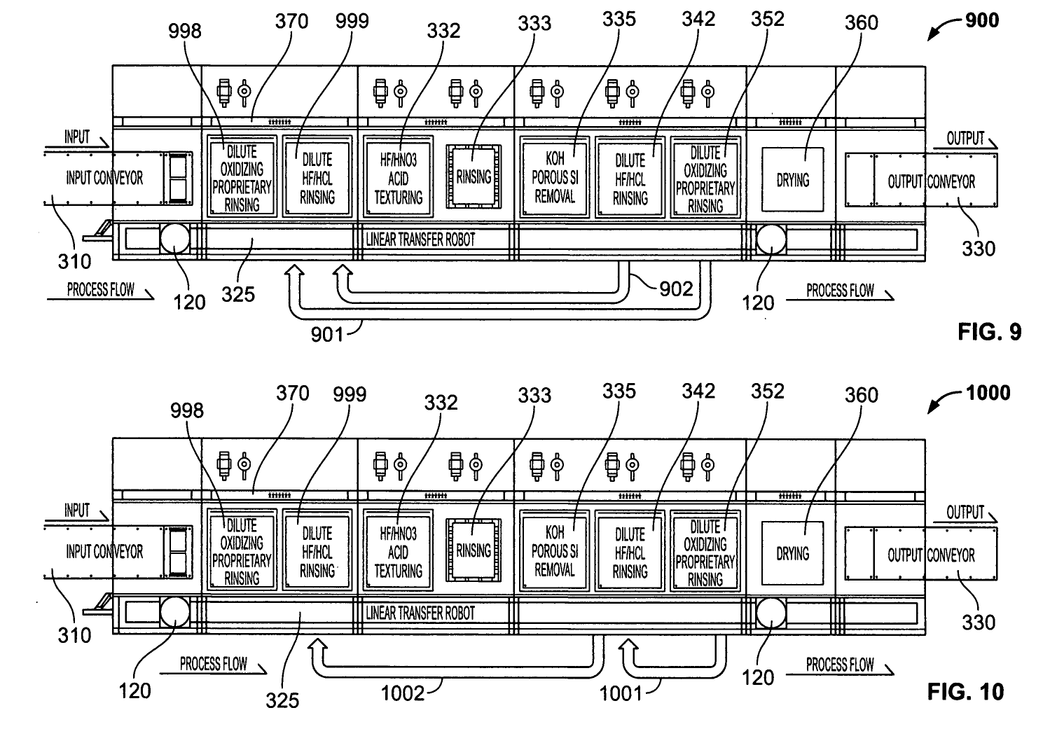

The apparatus structures 900, 1000 shown in FIGS. 9 and 10 are similar to those of FIG. 3, however, immediately prior to the HF/HNO₃ texturing bath 332, the silicon 120 or other material is pre-cleaned in a dilute oxidizing rinse 998 similar in chemical composition to the final rinse 352 described above in connection with FIG. 3 and is then treated to a dilute HF/HCl bath 999. It will be noted that other dilute baths could also be used as suggested above. FIGS. 9 and 10 show different alternatives for reuse of rinses when pre-cleaning is included in the process. In FIG. 9, the incoming high-purity water first is used in the dilute HF/HCl post-clean bath 342 and the water is then moved 902 and reused in the HF/HCl pre-clean bath 999 before being discarded. Additionally, new incoming high-purity water is first used in the dilute SC-1 or similar chemical post-clean bath 352; the water is then moved 901 for reuse as the SC-1 pre-clean rinse 998 before being discarded. The reused water may first be spiked with appropriate chemicals such as HF, HCl, SC-1 or the like. In FIG. 10 incoming high-purity water first is used in the dilute SC-1 or similar chemical post-clean bath 352, the rinse solution is then removed, spiked with HF and/or HCl and moved 1001 for use in the dilute HF/HCl post-clean bath 342. After this use, the rinse is again removed and, after, optionally, spiking with more HF and/or HCl, moved 1002 for use in the HF/HCl pre-clean bath 999 before being discarded.

It should be noted that he invention does not preclude additions to the processing, such as additional cleaning baths to remove particles, an additional final bath to render the surface hydrophilic instead of hydrophobic; or the inclusion of sonic agitation or other physical effect.

As demonstrated by the following Table 1, the current invention is anticipated to result in significant reductions in chemicals and water used in the processing of silicon wafers for solar cell applications from the conventional concentrated chemical method.

TABLE 1

| Concentrated Process | | | Simplified Process | | |
|---|---|---|---|---|---|
| | Number | Volume | | Number | Volume |
| | of Rinsing | Used | | of Rinsing | Used |
| Step | Tanks | (Liters) | Step | Tanks | (Liters) |
| HF/HNO₃ | 2 | 100 | HF/HNO₃ | 2 | 100 |
| Rinse | | | Rinse | | |
| Alkaline | 2 | 100 | Alkaline | 2 | 100 |
| Rinse | | | Rinse | | |
| HF/HCl | 2 | 100 | Dilute | 1 | 50 |
| Rinse | | | HF/HCl | | |
| Oxidizing | 2 | 100 | Proprietary | 1 | 50 |
| Rinse | | | Rinse | | |
| Final Rinse | 1 | 50 | | | |
| TOTAL | 9 | 450 | TOTAL | 6 | 300 |

The numbers for the concentrated process are actual bath volumes and rinsing cycles currently performed with concentrated chemicals using three dump rinse cycles on MTS equipment. The simplified process numbers include the anticipated volume reduction resulting from the elimination of one of the rinsing tanks. Additional reductions are achieved through the reuse of rinsing water.

As might be expected, the reuse of the water, cycling from one rinse tank to another, reduces the amount of water needed. Further, concentrated chemicals require large amounts of water to rinse the chemicals off the wafers to reach the desired low concentration levels, as the carry-over of chemical into the rinse water can be significant. Due to carry-over, the first stage of rinsing required that chemical to be neutralized and diluted to prevent further process, and then more water is used to render the wafer surface free of chemical. Less water is needed to rinse the concentrated chemicals; dilute baths are used that act as the rinsing process.

Furthermore, apparatus associated with the claimed method use less energy, exhaust, and materials, and have simpler facilitation requirements. The use of fewer baths and processing steps equates to a smaller system footprint and lower processing costs. Thus, an environmentally greener process is obtained when compared with the concentrated chemical process.

The invention may have applicability in other processes where multiple baths are needed, ultrahigh purity of water is not an issue and there are not high tolerances for surface cleanliness requirements of particles, metallic, or organic contamination. Such applications might include (i) silicon ingot, raw silicon, and poly silicon manufacturing; (ii) medical device cleaning; (iii) manufactured or milled parts cleaning; and (iv) panel cleaning, for LCD screens and solar panels or other similar parts. Therefore, while the present invention has been shown and described with reference to the foregoing preferred embodiments, it will be apparent to those skilled in the art that changes in form, connection, and detail may be made therein without departing from the spirit and scope of the invention as defined in the appended claims.

We claim:

1. A method for processing industrial material comprising the sequential steps of:
washing the material with dilute hydrogen fluoride/hydrogen chloride rinse;
washing the material with a first dilute oxidizing fluid, wherein the fluid comprises deionized water and an oxidizing agent selected from the group comprising ozone, SC-1 and hydrogen peroxide.

2. The method of claim 1, wherein the percent amount of hydrogen fluoride in the dilute hydrogen fluoride/hydrogen chloride rinse is between about 0.001 and 15 percent, and wherein the percent amount of hydrogen chloride in the dilute hydrogen fluoride/hydrogen chloride rinse is between about 0.001 to 15 percent.

3. The method of claim 1, wherein the first dilute oxidizing fluid comprises deionized water and ozone at a concentration between 1 to 70 parts per million.

4. The method of claim 1, wherein the first dilute oxidizing fluid comprises SC-1 at a ratio of about 100:1:1.

5. The method of claim 1, wherein the dilute oxidizing fluid comprises hydrogen peroxide at a ratio of about 10:1.

6. The method of claim 1, further comprising the step of
washing the material with a second dilute oxidizing fluid before the step of washing the material with dilute hydrogen fluoride/hydrogen chloride rinse.

7. The method of claim 1, further comprising the step of:
washing the material with an alkaline selected from the group comprising potassium hydroxide and sodium hydroxide immediately before the step of washing the material with dilute hydrogen fluoride/hydrogen chloride rinse.

8. The method of claim 6, further comprising the step of:
washing the material with concentrated hydrogen fluoride/nitric acid immediately before the step of washing the material with the second dilute oxidizing fluid.

9. The method of claim 1, comprising the further steps of:
collecting a portion of the first dilute oxidizing fluid after the step of washing the material with the first dilute oxidizing fluid;
spiking the portion with at least one of hydrogen fluoride and hydrogen chloride; and
using the spiked portion as part of the dilute hydrogen fluoride/hydrogen chloride rinse.

10. The method of claim 6, comprising the further steps of:
collecting a portion of the first dilute oxidizing fluid after the step of washing the material with the first dilute oxidizing fluid;
spiking the portion with at least one of hydrogen fluoride and hydrogen chloride; and
using the spiked portion as part of the dilute hydrogen fluoride/hydrogen chloride rinse.

11. The method of claim 6, comprising the further steps of:
collecting a portion of the first dilute oxidizing fluid after the step of washing the material with the first dilute oxidizing fluid;
spiking the portion of the first dilute oxidizing fluid with at least one of hydrogen fluoride and hydrogen chloride;
subsequently using the portion as part of the dilute hydrogen fluoride/hydrogen chloride rinse;
collecting a portion of the dilute hydrogen fluoride/hydrogen chloride rinse after the step of washing the material with dilute hydrogen fluoride/hydrogen chloride;
spiking the portion of the dilute hydrogen fluoride/hydrogen chloride rinse with an additional chemical selected from the group comprising: oxidizing fluid; hydrogen chloride; hydrogen fluoride; and combined HF/HCl; and
subsequently using the portion of the dilute hydrogen fluoride/hydrogen chloride rinse as part of the second dilute oxidizing fluid.

12. The method of claim 8, comprising the further sequential steps of:
prewashing the material with dilute oxidizing fluid, wherein the fluid comprises deionized water and an oxidizing agent selected from the group comprising ozone, SC-1 and hydrogen peroxide; and
prewashing the material with dilute hydrogen fluoride/hydrogen chloride rinse immediately before the step of washing the material with concentrated hydrogen fluoride/nitric acid.

13. The method of claim 12, further comprising the steps of:
collecting a portion of the dilute oxidizing fluid after the step of washing the material with dilute oxidizing fluid;
spiking the portion with at least one of hydrogen fluoride and hydrogen chloride; and
using the spiked portion as part of the dilute hydrogen fluoride/hydrogen chloride rinse in the step of washing with dilute hydrogen fluoride/hydrogen chloride rinse.

14. The method of claim 12, further comprising the steps of:
collecting a portion of the dilute hydrogen fluoride/hydrogen chloride rinse after the step of washing the material with dilute hydrogen fluoride/hydrogen chloride;
spiking the portion of the dilute hydrogen fluoride/hydrogen chloride rinse with at least one of hydrogen fluoride and hydrogen chloride; and
using the spiked portion of the dilute hydrogen fluoride/hydrogen chloride rinse as part of the dilute hydrogen fluoride/hydrogen chloride rinse in the step of prewashing the material with dilute hydrogen fluoride/hydrogen chloride rinse.

15. The method of claim 12, further comprising the steps of:
collecting a portion of the dilute oxidizing fluid after the step of washing the material with dilute oxidizing fluid; and
using the portion of the dilute oxidizing fluid as part of the dilute oxidizing fluid in the step of prewashing the material with dilute oxidizing fluid.

16. The method of claim 1, wherein the percent amount of hydrogen fluoride in the dilute hydrogen fluoride/hydrogen chloride rinse is between about 0.001 and 4 percent, and wherein the percent amount of hydrogen chloride in the dilute hydrogen fluoride/hydrogen chloride rinse is between about 0.001 to 1 percent.

17. The method of claim 6, wherein the second dilute oxidizing fluid is dilute hydrogen fluoride and ozone.

18. The method of claim 12, further comprising the steps of:
collecting a portion of the dilute oxidizing fluid after the step of washing the material with dilute oxidizing fluid;
spiking the portion of the dilute oxidizing fluid with an additional chemical selected from the group comprising: oxidizing fluid; hydrogen chloride; hydrogen fluoride; and combined HF/HCl;
using the portion of the dilute oxidizing fluid as part of the dilute oxidizing fluid in the step of prewashing the material with dilute oxidizing fluid.

19. The method of claim 13, further comprising the steps of:
collecting a portion of the dilute oxidizing fluid after the step of washing the material with dilute oxidizing fluid; and
using the portion of the dilute oxidizing fluid as part of the dilute oxidizing fluid in the step of prewashing the material with dilute oxidizing fluid.
